(19) United States
(12) Patent Application Publication
(10) Pub. No.: US 2018/0219148 A1
(43) Pub. Date: Aug. 2, 2018

(54) THERMOELECTRIC LEG, THERMOELECTRIC DEVICE COMPRISING THE SAME AND METHOD FOR MANUFACTURING THE SAME

(71) Applicant: LG INNOTEK CO., LTD., Seoul (KR)

(72) Inventor: Myoung Seok Sung, Seoul (KR)

(21) Appl. No.: 15/739,333

(22) PCT Filed: Jun. 24, 2016
(86) PCT No.: PCT/KR2016/006798

§ 371 Date: Dec. 22, 2017

(30) Foreign Application Priority Data
Jun. 25, 2015 (KR) 10-2015-0090737

(51) Int. Cl. H01L 35/10; H01L 35/16; H01L 35/18; H01L 35/32; H01L 35/08; H01L 35/34

(52) U.S. Cl. CPC H01L 35/10; H01L 35/16; H01L 35/34; H01L 35/32; H01L 35/08; H01L 35/18

(57) ABSTRACT

A thermoelectric element, according to one embodiment of the present invention, comprises: a first substrate; a plurality of thermoelectric legs disposed on the first substrate; and a second substrate disposed on the plurality of thermoelectric legs, wherein each of the thermoelectric legs comprises the bottom surface corresponding to the first substrate, the top surface corresponding to the second substrate, and at least one side surface between the bottom surface and the top surface, wherein at least one pair of a pair of the bottom surface and a side surface and a pair of the top surface and the side surface is connected by an extended surface.

### TECHNICAL FIELD

The present invention relates to a thermoelectric device, and more particularly, to a thermoelectric leg, a thermoelectric device including the thermoelectric leg, and a method of manufacturing the thermoelectric leg.

### BACKGROUND ART

A thermoelectric phenomenon is a phenomenon caused by movement of electrons and holes in a material and refers to a direct energy conversion between heat and electricity.

A thermoelectric device generally refers to a device using the thermoelectric phenomenon. Thermoelectric devices include a device using a temperature change of an electrical resistor, a device using a Seebeck effect, which is a phenomenon in which electromotive force is generated by a temperature difference, and a device using a Peltier effect, which is a phenomenon in which heat is absorbed or generated due to a current.

Thermoelectric devices are widely being applied to electronic appliances, electronic components, and communication components, and the demand for thermoelectric performance of the thermoelectric device is gradually increasing.

The thermoelectric device includes a substrate, an electrode, and a thermoelectric leg. The thermoelectric leg may be an important indicator that determines performance of the thermoelectric device. Generally, a thermoelectric material is thermally treated to manufacture an ingot, and the ingot is pulverized and sieved to obtain thermoelectric leg powder. Thereafter, the thermoelectric leg powder is sintered to obtain a thermoelectric leg sintered body. Further, the thermoelectric leg sintered body is cut to obtain a thermoelectric leg.

In this case, due to brittle characteristics of the thermoelectric material, there is a possibility that an edge of the thermoelectric leg will be broken when the thermoelectric leg sintered body is cut or when the thermoelectric device is manufactured. Since the broken edge can act as a resistive element, the broken edge may affect performance of the thermoelectric device, and productivity of the thermoelectric device may be reduced.

### DISCLOSURE

### Technical Problem

The present invention is directed to providing a thermoelectric leg having a processed edge, a thermoelectric device including the thermoelectric leg, and a method of manufacturing the thermoelectric leg.

### Technical Solution

One aspect of the present invention provides a thermoelectric device including a first substrate, a plurality of thermoelectric legs disposed on the first substrate, and a second substrate disposed on the plurality of thermoelectric legs. Each of the thermoelectric legs includes a bottom surface corresponding to the first substrate, a top surface corresponding to the second substrate, and at least one side surface between the bottom surface and the top surface, wherein at least one pair of a pair of the bottom surface and the side surface and a pair of the top surface and the side surface is connected by an extended surface.

Strength of the extended surface may be higher than strengths of the bottom surface and the top surface.

A height of the extended surface may be in a range of about 0.01 to 0.1 times a height of the side surface.

A sectional area of the extended surface may be smaller than a sectional area of the side surface.

The extended surface may have an inclination of about 30° to about 60° with respect to the bottom surface or the top surface.

The extended surface may include a first inclined surface configured to form a first angle with the bottom surface or the top surface, and a second inclined surface connected to the first inclined surface and configured to form a second angle with the bottom surface or the top surface.

The plurality of thermoelectric legs may include a plurality of P-type thermoelectric legs and a plurality of N-type thermoelectric legs. The plurality of P-type thermoelectric legs and the plurality of N-type thermoelectric legs may be electrically connected by a first electrode located between the first substrate and the bottom surface and a second electrode disposed between the second substrate and the top surface.

Another aspect of the present invention provides a thermoelectric leg including a bottom surface, a top surface, at least one side surface between the bottom surface and the top surface, and an extended surface configured to connect at least one pair of a pair of the bottom surface and the side surface and a pair of the top surface and the side surface.

The thermoelectric leg may be a bismuth telluride (Bi—Te)-based P-type thermoelectric leg or N-type thermoelectric leg.

Still another aspect of the present invention provides a method of manufacturing a thermoelectric leg. The method includes sintering thermoelectric leg powder by using a pressurizing member including a protrusion unit for an interfacial surface between thermoelectric legs, and cutting the sintered thermoelectric leg powder along a groove formed by the protrusion unit.

The sintering of the thermoelectric leg powder may be performed by a first pressurizing member configured to apply pressure to the thermoelectric leg powder from below and a second pressurizing member configured to apply pressure to the thermoelectric leg powder from above.

The thermoelectric leg powder may include bismuth (Bi) and tellurium (Te).

### Advantageous Effects

According to an exemplary embodiment of the present invention, a thermoelectric device having good performance can be obtained. In particular, a risk of breakage can be reduced by processing an edge of a thermoelectric leg, and a thermoelectric leg having uniform thermoelectric characteristics can be obtained when a device is manufactured using the thermoelectric leg.

### DESCRIPTION OF DRAWINGS

FIG. 1 is a cross-sectional view of a thermoelectric device according to an exemplary embodiment of the present invention.

FIG. 2 is a perspective view of the thermoelectric device according to the exemplary embodiment of the present invention.

FIG. 3 is a flowchart of a method of manufacturing a thermoelectric leg according to an exemplary embodiment of the present invention.

FIG. 4 is a diagram of a process of sintering thermoelectric leg powder to manufacture a thermoelectric leg according to an exemplary embodiment of the present invention;

FIG. 5 is a perspective view of a thermoelectric leg sintered body which is manufactured according to an exemplary embodiment of the present invention.

FIG. 6 is a perspective view of a thermoelectric leg manufactured according to an exemplary embodiment of the present invention.

FIGS. 7 to 11 are front views of the thermoelectric leg manufactured according to the exemplary embodiment of the present invention.

### MODES OF THE INVENTION

While the present invention is susceptible to various modifications and may take on various alternative forms, specific embodiments thereof are shown by way of example in the drawings and will be described herein in detail. However, it should be understood that there is no intent to limit the present invention to the particular forms disclosed. On the contrary, the present invention is to cover all modifications, equivalents, and alternatives falling within the spirit and scope of the claims.

It should be understood that, although the terms first, second, and the like may be used herein to describe various elements, these elements are not limited by these terms. The terms are only used to distinguish one element from another. For example, a first element could be termed a second element without departing from the scope of the present invention, and a second element could similarly be termed a first element. As used here, the term “and/or” includes any and all combinations of one or more of the associated listed items.

It should be understood that, when an element is referred to as being “connected” or “coupled” to another element, the element may be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It should be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It should be further understood that terms, such as those defined in commonly used dictionaries, should be interpreted as having a meaning that is consistent with their meaning in the context of the relevant art and are not to be interpreted in an idealized or overly formal sense unless expressly so defined here.

Hereinafter, exemplary embodiments will be described in detail with reference to the accompanying drawings. The same or corresponding elements are denoted by the same reference numerals regardless of drawings, and repeated descriptions thereof will be omitted.

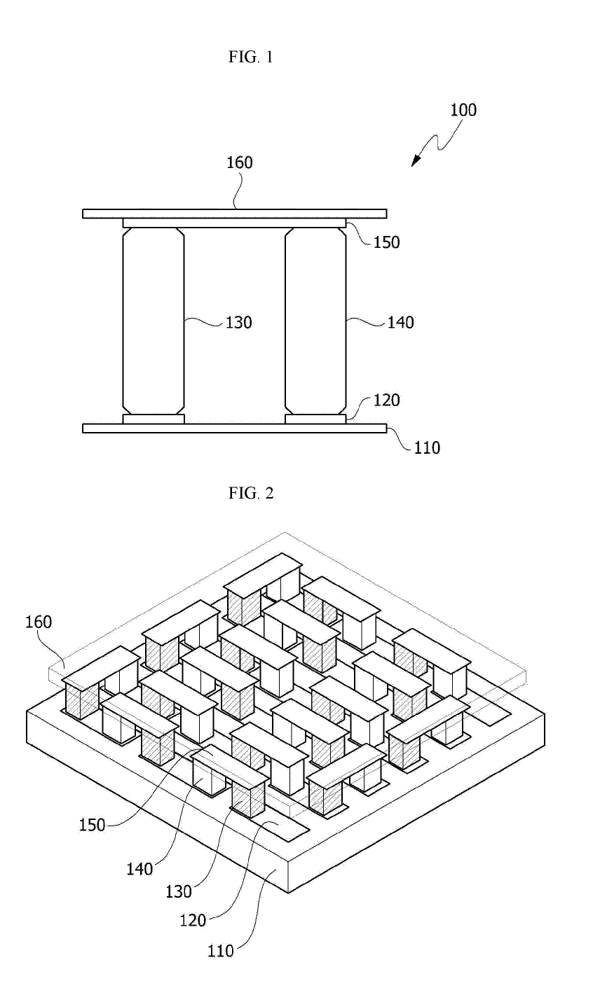

FIG. 1 is a cross-sectional view of a thermoelectric device according to an exemplary embodiment of the present invention, and FIG. 2 is a perspective view of the thermoelectric device according to the exemplary embodiment of the present invention.

Referring to FIGS. 1 and 2, a thermoelectric device 100 includes a lower substrate 110, a lower electrode 120, P-type thermoelectric legs 130, N-type thermoelectric legs 140, an upper electrode 150, and an upper substrate 160.

The lower electrode 120 is disposed between the lower substrate 110 and bottom surfaces of the P-type thermoelectric leg 130 and the N-type thermoelectric leg 140. The upper electrode 150 is disposed between the upper substrate 160 and top surfaces of the P-type thermoelectric leg 130 and the N-type thermoelectric leg 140. Thus, the plurality of P-type thermoelectric legs 130 and the plurality of N-type thermoelectric legs 140 are electrically connected by the lower electrode 120 and the upper electrode 150.

For example, when a direct-current (DC) voltage is applied to the lower electrode 120 through a lead line, the lower substrate 110 and the upper substrate 160 may act as a cooling unit or heating unit due to a Peltier effect.

To this end, the lower substrate 110 and the upper substrate 160 may be metal substrates, for example, Cu substrates, Cu alloy substrates, Cu—Al alloy substrates, or Al₂O₃ substrates. Further, the lower electrode 120 and the upper electrode 150 may include an electrode material, such as Cu, Ag, and Ni, and have a thickness ranging from about 0.01 mm to about 0.3 mm. Although not shown, a dielectric layer may be formed between the lower substrate 110 and the lower electrode 120 and between the upper substrate 160 and the upper electrode 150.

Here, the P-type thermoelectric leg 130 and the N-type thermoelectric leg 140 may be bismuth telluride (Bi—Te)-based thermoelectric legs containing bismuth (Bi) and tellurium (Ti) as main materials.

Performance of the thermoelectric device according to the exemplary embodiment of the present invention may be expressed with a Seebeck index ZT. The Seebeck index ZT may be expressed in Equation 1:

ZT=α²·σ·T/k Equation 1

wherein α denotes a Seebeck coefficient [V/K], σ denotes electrical conductivity [S/m], and a²σ denotes a power factor [W/mK²]. Further, T denotes a temperature, and k denotes thermal conductivity [W/mK]. k may be expressed as a·cₚ·p, wherein a denotes a thermal diffusivity [cm²/S], cₚ denotes a specific heat [J/gK], and ρ denotes a density [g/cm³].

In order to obtain the Seebeck index ZT of the thermoelectric device, a Z value (V/K) is measured using a Z meter, and the Seebeck index ZT may be calculated using the measured Z value. A thermoelectric leg may affect the Seebeck index ZT of the thermoelectric device. According to a zone melting method, after an ingot prepared by thermally treating a thermoelectric material is pulverized and sieved to obtain thermoelectric leg powder, the thermoelectric leg powder is sintered to obtain a thermoelectric leg sintered body. Then, the thermoelectric leg sintered body is primarily cut and plated, and the thermoelectric leg sintered body is secondarily cut to obtain a thermoelectric leg. In this case, due to brittle characteristics of the thermoelectric material, an edge of the thermoelectric leg may be broken when the thermoelectric leg sintered body is cut or when the thermoelectric device is manufactured. Since a broken edge may act as a resistive element, the broken edge may affect performance of the thermoelectric device, and productivity of the thermoelectric device may be reduced.

According to the exemplary embodiment of the present invention, the possibility of breakage of the edge of the thermoelectric leg is intended to be reduced by the edge of the thermoelectric leg being processed.

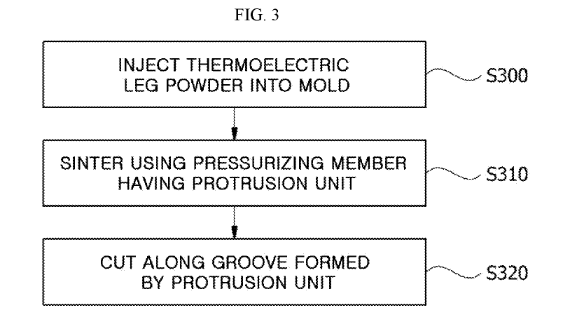

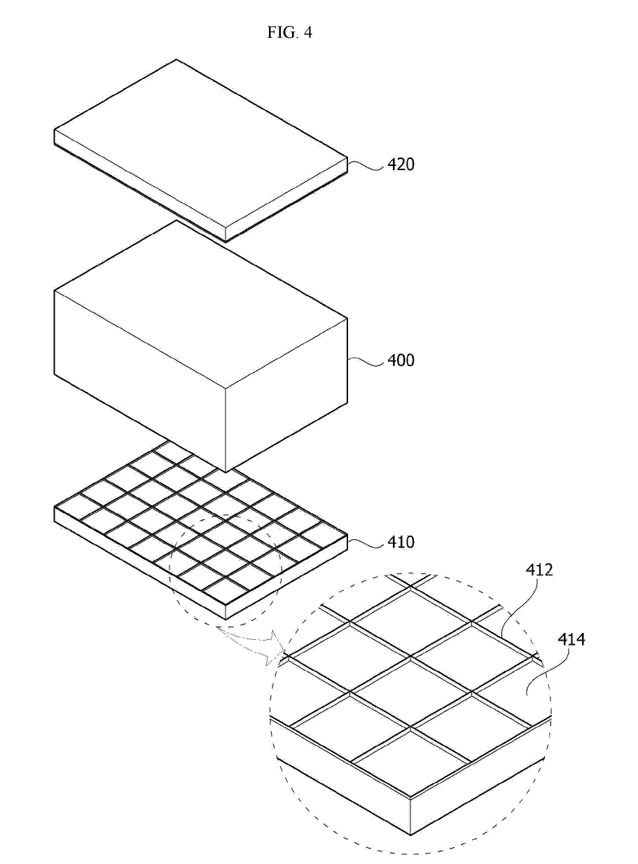

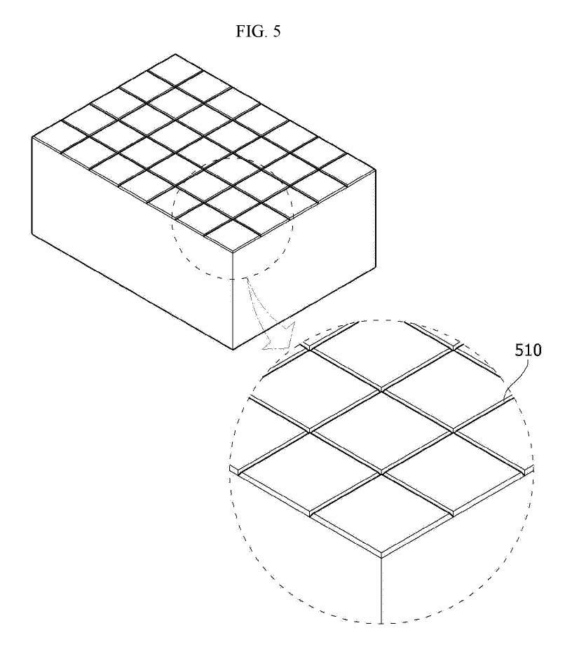

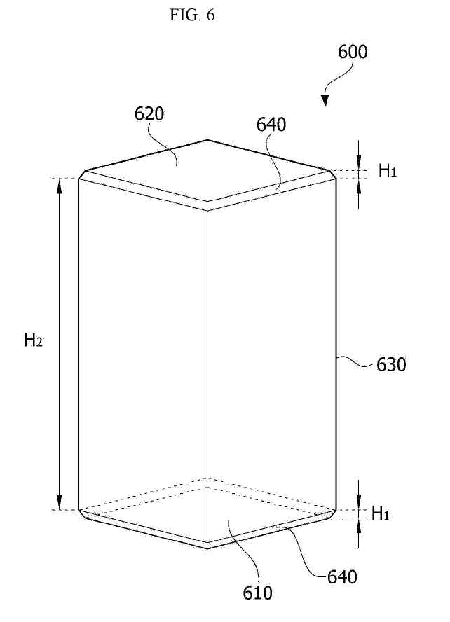

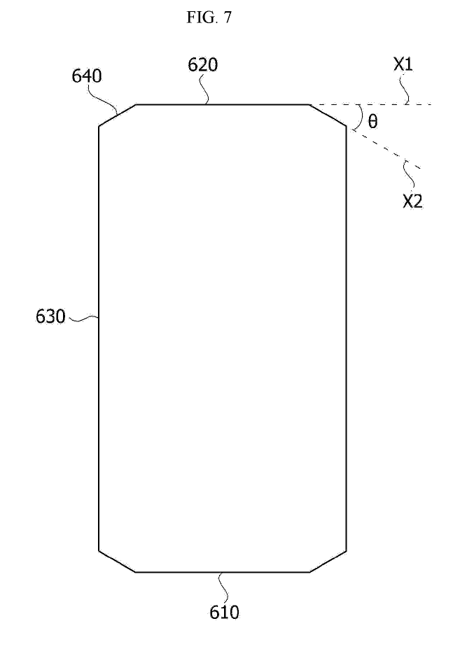

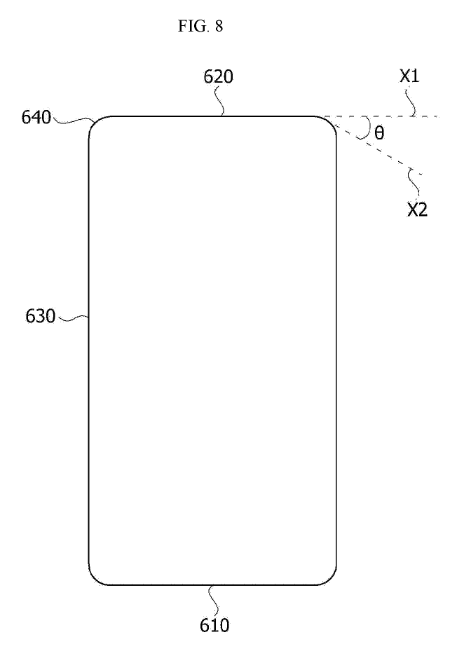

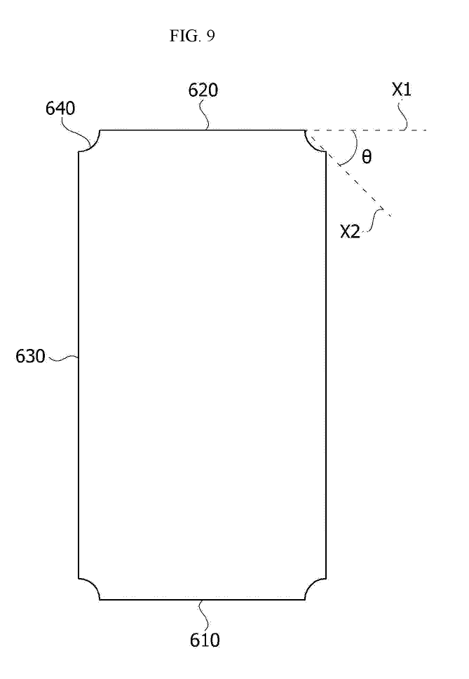

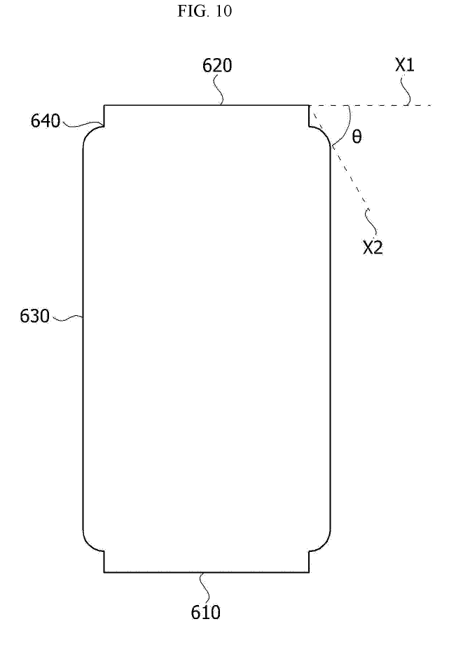

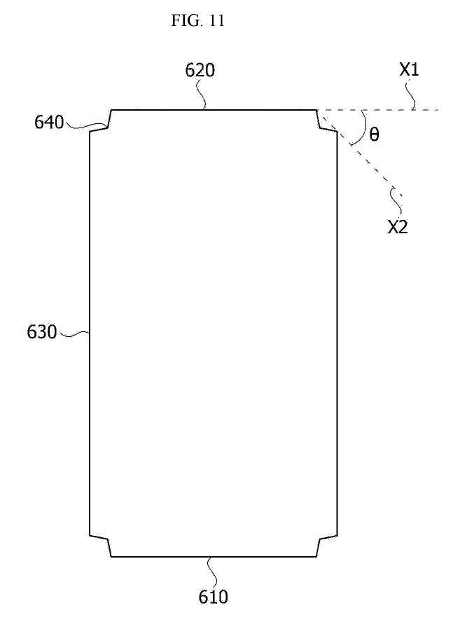

FIG. 3 is a flowchart of a method of manufacturing a thermoelectric leg according to an exemplary embodiment of the present invention. FIG. 4 is a diagram of a process of sintering thermoelectric leg powder to manufacture a thermoelectric leg according to an exemplary embodiment of the present invention. FIG. 5 is a perspective view of a thermoelectric leg sintered body which is manufactured according to an exemplary embodiment of the present invention. FIG. 6 is a perspective view of a thermoelectric leg, which is manufactured according to an exemplary embodiment of the present invention. FIGS. 7 to 11 are cross-sectional views of the thermoelectric leg according to the exemplary embodiment of the present invention.

Referring to FIG. 3, thermoelectric leg powder is injected into a mold (S300). Here, the thermoelectric leg powder may contain bismuth (Bi) and tellurium (Te), and may further include at least one of selenium (Se), antimony (Sb), silver (Ag), gold (Au), platinum (Pt), copper (Cu), nickel (Ni), and aluminum (Al). For example, powder for an N-type thermoelectric leg may contain Bi, Te, and Se at a ratio of Bi₂Te_{3-y}Se_{y} (0.1<y<0.4). Further, powder for a P-type thermoelectric leg may contain Bi, Sb, and Te at a ratio of Bi₂₋ₓSbₓTe₃ (0<x<1.8). The preparation of the thermoelectric leg powder may include manufacturing an ingot by annealing a raw material containing, for example, Bi and Te, and pulverizing and sieving the ingot. In this case, to pulverize the ingot, for example, a super mixer, a ball mill, an attrition mill, or a 3-roll mill may be used. The thermoelectric leg powder may have, for example, a grain size of micrometers.

Furthermore, the thermoelectric leg powder injected into the mold is sintered using a pressurizing member (S310). Referring to FIG. 4, pressurizing members 410 and 420 include protrusion units 412 and 422 for interfacial surfaces between thermoelectric legs and plane units 414 and 424 configured to apply pressure to a bottom surface 610 and a top surface 620 of a thermoelectric leg. Here, the pressurizing members 410 and 420 include a first pressurizing member 410 configured to apply pressure to the thermoelectric leg powder 400, which is injected into the mold, from below and a second pressurizing member 420 configured to apply pressure to the thermoelectric leg powder, which is injected into the mold, from above. In this case, the first pressurizing member 410 and the second pressurizing member 420 may be portions of a hot press apparatus. For example, the sintering process may be performed at a temperature of about 400° C. to about 550° C. under a pressure condition of about 180 MPa to about 250 MPa for about 1 minute to about 60 minutes. In this case, a depth of the mold may be about 1 to 1.2 times a height of the thermoelectric leg. In this case, the sintering process may be performed for a short amount of time, for example, about 10 minutes or less. When the sintering process is finished in a short amount of time, excessive growth of grains may be prevented to increase thermoelectric efficiency. Further, when the depth of the mold is about 1 to 1.2 times the height of the thermoelectric leg, heat is uniformly supplied to an upper portion and a lower portion of the mold to reduce a difference of thermoelectric efficiency among positions in a sintered body. Referring to FIG. 5, a groove 510 is formed due to the protrusion units 412 and 422 of the pressurizing members 410 and 420 in a thermoelectric leg sintered body 500.

Next, the thermoelectric leg sintered body 500 is cut along the groove 510 formed therein (S320). Thus, the thermoelectric leg according to the exemplary embodiment of the present invention may be obtained.

Referring to FIG. 6, a thermoelectric leg 600 according to the exemplary embodiment of the present invention includes a bottom surface 610, a top surface 620, and a side surface 630 formed between the bottom surface 610 and the top surface 620. The bottom surface 610 and the side surface 630 are connected by an extended surface 640, and the top surface 620 and the side surface 630 are connected by the extended surface 640.

Here, the bottom surface 610 may be a surface corresponding to the lower substrate 110 of the thermoelectric device 100 shown in FIGS. 1 and 2. The bottom surface 610 may be a surface disposed parallel to the lower substrate 110 and in contact with the lower electrode 120. Similarly, the top surface 620 may be a surface corresponding to the upper substrate 160 of the thermoelectric device 100 shown in FIGS. 1 and 2. The top surface 620 may be a surface disposed parallel to the upper substrate 160 and in contact with the upper electrode 150.

Here, the bottom surface 610 and the top surface 620 are formed by pressure applied by the plane units 414 and 424 of the pressurizing members 410 and 420. The extended surface 640 is formed by pressure applied by the protrusion units 412 and 422 of the pressurizing members 410 and 420. The side surface 630 may be formed by cutting the thermoelectric leg sintered body 500.

Thus, pressure applied to the extended surface 640 is higher than pressure applied to the bottom surface 610 and the top surface 620 of the thermoelectric leg 600. Thus, strength of the extended surface 640 is higher than strengths of the bottom surface 610 and the top surface 620, and the possibility of breakage of the extended surface 640 due to an external impact or a cutting process is reduced.

Here, a height H1 of the extended surface 640 may be in a range of about 0.01 to 0.1 times a height H2 of the side surface 630. Thus, a volume of the thermoelectric leg according to the exemplary embodiment of the present invention is about 99.5% to about 99.9% of a volume of the thermoelectric leg having an unprocessed edge. As a result, an edge of the thermoelectric leg may be protected without affecting thermoelectric performance of the thermoelectric leg. However, when the height H1 of the extended surface 640 is less than 0.01 times the height H2 of the side surface 630, an effect of protecting against breakage of the edge of the thermoelectric leg 600 may be degraded. Further, when the height H1 of the extended surface 640 exceeds about 0.1 times the height H2 of the side surface 630, strength of the thermoelectric leg 600 may be reduced and thermoelectric performance may be lowered.

In addition, the extended surface 640 may have an inclination of about 30° to about 60° with respect to the bottom surface 610 or the top surface 620. Thus, a sectional area of a section of the extended surface 640 is smaller than a sectional area of a section of the side surface 630. When an angle θ between the extended surface 640 and the bottom surface 610 or the top surface 620 is less than 30° or more than 60°, an effect of protecting against the breakage of the edge of the thermoelectric leg 600 may be reduced or the strength or performance of the thermoelectric leg may be reduced. Here, the angle θ between the extended surface 640 and the bottom surface 610 or the top surface 620 may refer to an angle between a line or plane X1, which is parallel to the bottom surface 610 or the top surface 620, and a line or plane X2 connecting an interface between the bottom surface 610 or the top surface 620 and the extended surface 640 and an interface between the extended surface 640 and the side surface 630.

Meanwhile, a shape of the extended surface 640 may vary according to shapes of the protrusion units 412 and 422 of the pressurizing members 410 and 420. In an example, when sections of the protrusion units 412 and 422 have V shapes, the extended surface 640 may be formed as an inclined flat surface, as shown in FIG. 7. In another example, as shown in FIGS. 8 to 11, the extended surface 640 may be formed to have a predetermined curvature, a step, or at least two inclined surfaces having different inclination angles according to the shape of the sections of the protrusion units 412 and 422.

As described above, according to the exemplary embodiment of the present invention, strength of an edge portion of the thermoelectric leg is increased, and the edge portion of the thermoelectric leg is inclined or depressed so that the chance of the thermoelectric leg coming into contact with the outside may be reduced. Thus, productivity of the thermoelectric leg may be increased, and the thermoelectric leg may have uniform thermoelectric characteristics when a device is formed.

Furthermore, according to the exemplary embodiment of the present invention, since the thermoelectric leg is obtained by sintering thermoelectric leg powder in a mold and performing only one cutting process, material loss due to a plurality of cutting processes may be reduced.

In addition, according to the exemplary embodiment of the present invention, since the thermoelectric leg powder is sintered in the mold for a short amount of time, uniform thermoelectric performance may be obtained regardless of a position in the sintered body.

While the present invention has been particularly shown and described with reference to exemplary embodiments thereof, it should be understood that various changes in form and details may be made therein without departing from the spirit and scope of the following claims.

### DESCRIPTION OF SYMBOLS

100: thermoelectric device

110: lower substrate

120: lower electrode

130: P-type thermoelectric leg

140: N-type thermoelectric leg

150: upper electrode

160: upper substrate

1. A thermoelectric device comprising:
a first substrate;
a plurality of thermoelectric legs disposed on the first substrate; and
a second substrate disposed on the plurality of thermoelectric legs,
wherein each of the thermoelectric legs comprises a bottom surface corresponding to the first substrate, a top surface corresponding to the second substrate, and at least one side surface between the bottom surface and the top surface,
wherein at least one pair of a pair of the bottom surface and the side surface and a pair of the top surface and the side surface is connected by an extended surface.

2. The thermoelectric device of claim 1, wherein strength of the extended surface is higher than strengths of the bottom surface and the top surface.

3. The thermoelectric device of claim 1, wherein a height of the extended surface is in a range of 0.01 to 0.1 times a height of the side surface.

4. The thermoelectric device of claim 1, wherein a sectional area of the extended surface is smaller than a sectional area of the side surface.

5. The thermoelectric device of claim 1, wherein the extended surface has an inclination of 30° to 60° with respect to the bottom surface or the top surface.

6. The thermoelectric device of claim 1, wherein the extended surface comprises:
a first inclined surface configured to form a first angle with the bottom surface or the top surface; and
a second inclined surface connected to the first inclined surface and configured to form a second angle with the bottom surface or the top surface.

7. The thermoelectric device of claim 1, wherein the plurality of thermoelectric legs comprise a plurality of P-type thermoelectric legs and a plurality of N-type thermoelectric legs,
wherein the plurality of P-type thermoelectric legs and the plurality of N-type thermoelectric legs are electrically connected by a first electrode located between the first substrate and the bottom surface and a second electrode disposed between the second substrate and the top surface.

8. A thermoelectric leg comprising:
a bottom surface;
a top surface;
at least one side surface between the bottom surface and the top surface; and
an extended surface configured to connect at least one pair of a pair of the bottom surface and the side surface and a pair of the top surface and the side surface.

9. The thermoelectric leg of claim 8, wherein strength of the extended surface is higher than strengths of the bottom surface and the top surface.

10. The thermoelectric leg of claim 8, wherein a height of the extended surface is in a range of 0.01 to 0.1 times a height of the side surface.

11. The thermoelectric leg of claim 8, wherein a sectional area of the extended surface is smaller than a sectional area of the side surface.

12. The thermoelectric leg of claim 8, wherein the thermoelectric leg is a bismuth telluride (Bi—Te)-based P-type thermoelectric leg or N-type thermoelectric leg.

13. The thermoelectric leg of claim 8, wherein the extended surface has an inclination of 30° to 60° with respect to the bottom surface or the top surface.

14. The thermoelectric leg of claim 8, wherein the extended surface comprises:
a first inclined surface configured to form a first angle with the bottom surface or the top surface; and
a second inclined surface connected to the first inclined surface and configured to form a second angle with the bottom surface or the top surface.

15. (canceled)
